(19) United States
(12) Patent Application Publication
(10) Pub. No.: US 2024/0111921 A1
(43) Pub. Date: Apr. 4, 2024

(54) METHOD AND DEVICE WITH BATTERY MODEL OPTIMIZATION

(71) Applicants: SAMSUNG ELECTRONICS CO., LTD., Suwon-si (KR); POSTECH Research and Business Development Foundation, Pohang-si (KR)

(72) Inventors: Jungsoo KIM, Suwon-Si (KR); Joonhee KIM, Pohang-si (KR); Jinho KIM, Suwon-si (KR); Myeongjae LEE, Suwon-si (KR); Huiyong CHUN, Pohang-si (KR); Soohee HAN, Pohang-si (KR)

(73) Assignees: SAMSUNG ELECTRONICS CO., LTD., Suwon-si (KR); POSTECH Research and Business Development Foundation, Pohang-si (KR)

(21) Appl. No.: 18/331,363

(22) Filed: Aug. 28, 2023

(30) Foreign Application Priority Data
Sep. 13, 2022 (KR) 10-2022-0114863
Dec. 21, 2022 (KR) 10-2022-0180837

(51) Int. Cl. G06F 30/20

(52) U.S. Cl. CPC G06F 30/20

(57) ABSTRACT

A processor-implemented method includes performing first parameter optimization of a battery model through a first predetermined optimization technique; switching, based on a count accumulated while performing the first parameter optimization indicating that a switching criterion has been met, from the first optimization technique to a second predetermined optimization technique; performing second parameter optimization of the battery model through the second predetermined optimization technique; and determining a final parameter combination as an optimized parameter of the battery model, in response to an occurrence of an optimization end event during the performance of the second parameter optimization.

### CROSS-REFERENCE TO RELATED APPLICATIONS

This application claims the benefit under 35 USC § 119(a) of Korean Patent Application No. 10-2022-0114863, filed on Sep. 13, 2022, and Korean Patent Application No. 10-2022-0180837, filed on Dec. 21, 2022, in the Korean Intellectual Property Office, the entire disclosures of which are incorporated herein by reference for all purposes.

### BACKGROUND

### 1. Field

The following disclosure relates to a method and device with battery mode optimization.

### 2. Description of Related Art

Typical battery state estimation may be performed based on an equivalent circuit model (ECM). An ECM is an empirical model that simulates an electrical behavior of a battery using passive elements (e.g., a resistor, an inductor, a capacitor, etc.), but the use of ECMs is limited. To complement the ECM, an electrochemical model is designed to describe the electrochemical behavior of the battery based on the basic principles (e.g., the law of conservation of mass, the law of conservation of charge, etc.).

An electrochemical model may attempt to simulate the behavior of the battery and thus be useful for diagnosing and predicting the state of the battery in combination with a thermal model and a degradation model. However, since the electrochemical model includes many parameters and different combinations thereof depending on the type of battery, use of the electrochemical model is often problematic due to the prerequisite that each of the parameters be accurately identified.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a processor-implemented method may include performing first parameter optimization of a battery model through a first predetermined optimization technique; switching, based on a count accumulated while performing the first parameter optimization indicating that a switching criterion has been met, from the first optimization technique to a second predetermined optimization technique; performing second parameter optimization of the battery model through the second predetermined optimization technique; and determining a final parameter combination as an optimized parameter of the battery model, in response to an occurrence of an optimization end event during the performance of the second parameter optimization.

The performing of the first parameter optimization may include generating, in a current iteration of the first parameter optimization, objective function values for parameter combinations to which the first optimization technique is applied; selecting one of the generated objective function values; comparing the selected one objective function value with a previously determined best objective function value, determined in a previous iteration of the first parameter optimization; accumulating the count when the selected one objective function value is determined to be greater than or equal to the previously determined best objective function value; and determining the selected one objective function value as a new best objective function value when the selected one objective function value is determined to be less than the previously determined best objective function value.

The generating of the objective function values for the parameter combinations may include calculating voltages using a simulator configured to simulate the battery model, the parameter combinations, and reference current data; and calculating the objective function values for the parameter combinations using the calculated voltages and reference voltage data.

The switching criterion may be satisfied when the accumulated count reaches a threshold value.

The switching may include determining one of a plurality of baseline functions using parameter combinations determined when the switching criterion is satisfied, objective function values for the determined parameter combinations, and a neural network; and selecting the second optimization technique based on the determined baseline function.

The determining of one of the plurality of baseline functions may include determining the baseline function in consideration of a distribution of the determined parameter combinations and the objective function values through the neural network.

The selecting of the second optimization technique may include determining whether the determined baseline function corresponds to a baseline function for evaluating a performance of the second optimization technique among a plurality of optimization techniques; and selecting the second optimization technique when the determined baseline function corresponds to the baseline function.

The method may further include initializing the accumulated count.

The performing of the second parameter optimization may include updating parameter combinations determined when the switching criterion is satisfied through the second optimization technique.

The performing of the second parameter optimization may include, in response to a predetermined condition being satisfied, extracting parameter combinations from an area other than a distribution area of parameter combinations determined when the switching criterion is satisfied.

In another general aspect, an electronic device may include one or more processors configured to execute instructions; and a memory configured to store the instructions, wherein the execution of the instructions by the one or more processors configures the one or more processors to perform first parameter optimization of a battery model through a first predetermined optimization technique; switch, based on a count accumulated while performing the first parameter optimization indicating that a switching criterion has been met, from a first optimization technique to a second predetermined optimization technique; perform second parameter optimization of the battery model through the second optimization technique; and determine a final parameter combination as an optimized parameter of the battery model, in response to an occurrence of an optimization end event during the performance of the second parameter optimization.

The one or more processors may be further configured to generate, in a current iteration of the first parameter optimization, objective function values for parameter combinations to which the first optimization technique is applied; select one of the generated objective function values; compare the selected one objective function value with a previously determined best objective function value, determined in a previous iteration; accumulate the count when the selected one objective function value is determined to be greater than or equal to the previously determined best objective function value; and determine the selected one objective function value as a new best objective function value when the selected one objective function value is determined to be less than the previously determined best objective function value.

The one or more processors may be further configured to calculate voltages using a simulator configured to simulate the battery model, the parameter combinations, and reference current data; and calculate the objective function values for the parameter combinations using the calculated voltages and reference voltage data.

The one or more processors may be further configured to determine that the switching criterion is satisfied, when the accumulated count reaches a threshold value.

The one or more processors may be further configured to determine one of a plurality of baseline functions using parameter combinations determined when the switching criterion is satisfied, objective function values for the parameter combinations, and a neural network; and select the second optimization technique based on the determined baseline function.

The one or more processors may be further configured to determine the baseline function in consideration of a distribution of the parameter combinations and the objective function values through the neural network.

The one or more processors may be further configured to determine whether the determined baseline function corresponds to a baseline function for evaluating a performance of the second optimization technique among a plurality of optimization techniques; and select the second optimization technique when the determined baseline function corresponds to the baseline function.

The one or more processors may be further configured to initialize the accumulated count.

The one or more processors may be further configured to update parameter combinations determined when the switching criterion is satisfied through the second optimization technique.

The one or more processors may be further configured to, in response to a predetermined condition being satisfied, extract parameter combinations from an area other than a distribution area of parameter combinations determined when the switching criterion is satisfied.

Other features and aspects will be apparent from the following detailed description, the drawings, and the claims.

### BRIEF DESCRIPTION OF THE DRAWINGS

FIG. 1 illustrates an example electronic device with battery model optimization according to one or more embodiments.

FIGS. 2 through 4 illustrate an example method of optimizing a battery model according to one or more embodiments.

FIGS. 5 through 7B illustrate an example operation of determining a baseline function using a neural network by an electronic device according to one or more embodiments.

FIG. 8 illustrates an example method of optimizing a battery model according to one or more embodiments.

FIG. 9 illustrates an example operation of switching an optimization while a battery model optimization method is performed according to one or more embodiments.

FIG. 10 illustrates an example comparison in voltage error measurement between a battery model optimization method according to one or more embodiments and an typical optimization approach.

FIG. 11 illustrates an example comparison, in a standard deviation of voltage errors and a standard deviation of estimated parameters, between a battery model optimization method according to one or more embodiments and a typical single optimization approach.

FIG. 12 illustrates an example electronic device according to one or more embodiments.

FIG. 13 illustrates an example battery model optimization method according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C’, and the like are intended to have disjunctive meanings, and these phrases “at least one of A, B, and C”, “at least one of A, B, or C’, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing. It is to be understood that if a component (e.g., a first component) is referred to, with or without the term “operatively” or “communicatively,” as “coupled with,” “coupled to,” “connected with,” or “connected to” another component (e.g., a second component), it means that the component may be coupled with the other component directly (e.g., by wire), wirelessly, or via a third component.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein.

Typical parameter identification requires measure parameters through operations such as electrochemical impedance spectroscopy (EIS), X-ray diffraction (XRD), scanning electron microscope (SEM), and the like. As these typical operations not only have certain limitations in measuring parameters, but also time consuming and costly, it is found herein to be beneficial to use at least an alternate method and device to identify parameters using various optimization techniques.

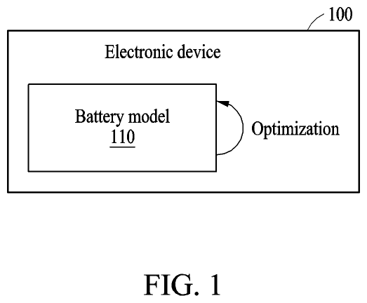

FIG. 1 illustrates an example electronic device for optimizing a battery model according to one or more embodiments.

Referring to FIG. 1, an electronic device 100 may be configured to optimize a battery model 110. The electronic device 100 may include one or more processors configured to execute instructions and one or more memories storing the instructions. The execution of the instructions by the one or more processors may configure the one or more processors to perform any one or any combinations of operations or method described herein.

The battery model 110 may include an electrochemical model. As non-limiting examples, the electrochemical model may simulate an internal state of a battery using, for example, one or more parameters and one or more mathematical equations (e.g., governing equations). The electrochemical model may include, for example, a pseudo-2-dimensional (P2D) model, a reduced order model (ROM), a single particle model (SPM), and the like, but is not limited thereto. Hereinafter, a battery simulated by the battery model 110 will be referred to as a “target battery”.

The electronic device 100 may optimize the battery model 110 by optimizing one or more parameters of the battery model 110. Table 1 below shows an example of one or more parameters of the battery model 110.

TABLE 1

| Symbol | Description |
|---|---|
| θₚ^{max}, θₚ^{min}, θₙ^{max}, θₙ^{min} | Stoichiometry limit |
| Rₚ, Rₙ | Solid particle radius |
| σₚ, σₙ | Solid-phase conductivity |
| ϵₚ, ϵₛ, ϵₙ | Electrolyte porosity |
| ϵ_{f, p}, ϵ_{f, n} | Filler fraction |
| aₚ, aₙ | Particle specific surface area |
| Dₑ, Dₚ, Dₙ | Diffusivity |
| cₑ^{init} | Initial lithium concentration |
| R_{SEI} | SEI layer resistance |
| kₚ, kₙ | Reaction rate constant |
| R_{ISC} | ISC equivalent resistance |

In Table 1 above, p and n denote a cathode and an anode of the target battery, respectively, s and e denote a separator and an electrolyte of the target battery, respectively, init denotes an initial value, SEI denotes a solid electrolyte interface, and ISC denotes an internal short circuit.

The one or more parameters of the battery model 110 are not limited to those shown in Table 1 above.

The electronic device 100 may be configured to perform parameter optimization using one of a plurality of optimization techniques (or metaheuristic techniques) (e.g., swarm intelligence-based algorithm (SIA) techniques).

As non-limiting examples, the optimization techniques may include particle swarm optimization (PSO) algorithm, bald eagle search (BES) algorithm, gray wolf optimization (GWO) algorithm, honey badger algorithm (HBA), salp swarm algorithm (SSA), etc. However, the optimization techniques are not limited to the algorithms mentioned above. Each algorithm may determine an optimal solution to a given problem in a distinct and independent manner.

The electronic device 100 may be configured with baseline functions for evaluating the performances of the optimization techniques. Tables 2 and 3 below show examples of baseline functions of the electronic device 100. In Fi (where i=1 to 23) in Tables 2 and 3 below, i denotes an index of a baseline function.

TABLE 2

| | Parameter |
|---|---|
| Function | Range |
| F₁(θ) = Σᵢ₌₁ⁿ θᵢ² | [−100, 100] |
| F₂(θ) = Σᵢ₌₁ⁿ \|θᵢ\| + Πᵢ₌₁ⁿ \|θᵢ\| | [−10, 10] |
| F₃(θ) = Σᵢ₌₁ⁿ (Σⱼ₌₁ⁱ θⱼ)² | [−100, 100] |
| F₄(θ) = maxᵢ{\|θᵢ\|, 1 ≤ i ≤ n} | [−100, 100] |
| F₅(θ) = Σᵢ₌₁ⁿ⁻¹ {100(θᵢ₊₁ − θᵢ²)² + (θᵢ − 1)²} | [−30, 30] |
| F₆(θ) = Σᵢ₌₁ⁿ (θᵢ + 0.5)² | [−100, 100] |
| F₇(θ) = Σᵢ₌₁ⁿ iθᵢ⁴ + random[0, 1) | [−1.28, 1.28] |
| F₈(θ) = Σᵢ₌₁ⁿ −θᵢ sin \sqrt{\|θᵢ\|} | [−500, 500] |
| F₉(θ) = Σᵢ₌₁ⁿ (θᵢ² − 10 cos 2πθᵢ + 10) | [−5.12, 5.12] |
| ${F}_{10} ( θ ) = - 20 exp ( - 0.2 \sqrt{\frac{1}{n} {\sum }_{i = 1}^{n} {θ}_{i}^{2}} ) -$ | [−32, 32] |
| $exp ( \frac{1}{n} {\sum }_{i = 1}^{n} cos 2 π {θ}_{i} ) + 20 + e$ | |
| ${F}_{11} ( θ ) = \frac{1}{4000} {\sum }_{i = 1}^{n} {θ}_{i}^{2} - {\prod }_{i = 1}^{n} cos \frac{{θ}_{i}}{\sqrt{i}} + 1$ | [−600, 600] |
| ${F}_{12} ( θ ) = {\sum }_{i = 1}^{n} u ( {θ}_{i}^{2} , 10 , 100 , 4 ) + \frac{x}{n} [ 10 sin π {y}_{i}$ | |
| Σᵢ₌₁ⁿ⁻¹ (yᵢ − 1)²{1 + 10 sin² πyᵢ₊₁}² + yₙ − 1], | |
| $where {y}_{i} = 1 + \frac{{θ}_{i} + 1}{4} ,$ | [−50, 50] |
| $\begin{matrix}u ( {θ}_{i} , a , k , m ) = {k ( \vert {θ}_{i} \vert - a )}^{m} & if \vert {θ}_{i} \vert > a \\ = 0 & otherwise\end{matrix}$ | |

TABLE 3

| | Parameter |
|---|---|
| Function | Range |
| F₁₃(θ) = Σᵢ₌₁ⁿ u(θᵢ², 5, 100, 4) + 0.1[sin² 3πθ₁ + | [−50, 50] |
| Σᵢ₌₁ⁿ (θᵢ − 1)²{1 + sin(3πθᵢ + 1)} + | |
| (θₙ − 1)²{1 + sin 2πθₙ}] | |
| ${F}_{14} ( θ ) = {\{ \frac{1}{500} + {\sum }_{j = 1}^{25} \frac{1}{j + {\sum }_{i = 1}^{2} {( {θ}_{i} - {a}_{ij} )}^{6}} \}}^{- 1}$ | [−65, 65] |
| ${F}_{15} ( θ ) = {\sum }_{i = 1}^{11} {\{ {a}_{i} - \frac{{θ}_{i} ( {b}_{i}^{2} + {b}_{i} {θ}_{2} )}{{b}_{i}^{2} + {b}_{i} {θ}_{3} + {θ}_{4}} \}}^{2}$ | [−5, 5] |
| ${F}_{16} ( θ ) = 4 {θ}_{1}^{2} - 2.1 {θ}_{1}^{4} + \frac{1}{3} {θ}_{1}^{6} + {θ}_{1} {θ}_{2} - 4 {θ}_{2}^{2} + 4 {θ}_{2}^{4}$ | [−5, 5] |
| $\begin{matrix}{F}_{17} ( θ ) = {( {θ}_{2} - \frac{5.1}{4 {π}^{2}} {θ}_{1}^{2} + \frac{5}{π} {θ}_{1} - 6 )}^{2} + \\ 10 ( 1 - \frac{1}{8 π} ) cos {θ}_{1} + 1\end{matrix}$ | [−5, 5] |
| $\begin{matrix}{F}_{18} ( θ ) = \{ 1 + {( {θ}_{1} + {θ}_{2} + 1 )}^{2} ( 19 - 14 {θ}_{1} + 3 {θ}_{1}^{2} - \\ 14 {θ}_{2} + 6 {θ}_{1} {θ}_{2} + 3 {θ}_{2}^{2} ) \} \{ 30 + {( 2 {θ}_{1} - 3 {θ}_{2} )}^{2} ( 18 - \\ 32 {θ}_{1} + 12 {θ}_{1}^{2} + 48 {θ}_{2} - 36 {θ}_{1} {θ}_{2} + 27 {θ}_{2}^{2} ) \}\end{matrix}$ | [−2, 2] |
| F₁₉(θ) = −Σᵢ₌₁⁴ cᵢ exp{−Σⱼ₌₁³ aᵢⱼ(θⱼ − pᵢⱼ)} | [1, 3] |
| F₂₀(θ) = −Σᵢ₌₁⁴ cᵢ exp{−Σⱼ₌₁⁶ aᵢⱼ(θⱼ − pᵢⱼ)} | [0, 1] |
| F₂₁(θ) = −Σᵢ₌₁⁵ {(θ − aᵢ)(θ − aᵢ)^{T} + cᵢ}⁻¹ | [0, 10] |
| F₂₂(θ) = −Σᵢ₌₁⁷ {(θ − aᵢ)(θ − aᵢ)^{T} + cᵢ}⁻¹ | [0, 10] |
| F₂₃(θ) = −Σᵢ₌₁¹⁰ {(θ − aᵢ)(θ − aᵢ)^{T} + cᵢ}⁻¹ | [0, 10] |

As will be described later, the electronic device 100 may be configured to determine or identify, using a machine leaning model (e.g., a neural network), as a non-limiting example, a baseline function having a distribution similar to the distribution of given parameter combinations and the objective function value of each parameter combination.

The electronic device 100 may be configured to classify the plurality of optimization techniques and identify/determine/select an optimization technique having relatively better optimization performance (compared to the other optimization techniques) for a corresponding baseline function Fi. Table 4 below shows an example of classification results. In SIAj in Table 4 below (where j=1 to 5), j denotes an index of an optimization technique.

TABLE 4

| Algorithm | ID | Cost functions |
|---|---|---|
| BES | SIA₁ | F₁, F₂, F₃, F₄, F₉, F₁₀, F₁₁ |
| GWO | SIA₂ | F₅, F₁₃, F₁₅, F₂₀ |
| HBA | SIA₃ | F₇, F₁₂ |
| PSO | SIA₄ | F₈, F₁₄, F₁₉ |
| SSA | SIA₅ | F₆, F₁₆, F₁₇, F₁₈, F₂₁, F₂₂, F₂₃ |

The cost functions in Table 4 above represent the baseline functions described above.

The BES algorithm may have relatively better optimization performance in baseline functions F1, F2, F3, F4, F9, F10, and F11 among all the baseline functions F1-F23. In other words, the electronic device 100 may evaluate the performance of the BES algorithm through each of the baseline functions F1 through F23, and the performance of the BES algorithm may be relatively highly evaluated in the baseline functions F1, F2, F3, F4, F9, F10, and F11 compared to the other baseline functions F5-F8 and F12-F23. In this example, the electronic device 100 may map the baseline functions F1, F2, F3, F4, F9, F10, and F11 to the BES algorithm as shown in Table 4 above.

The GWO algorithm may have relatively better optimization performance in baseline functions F5, F13, F15, and F20 compared to the other baseline functions F1-F4, F6-F12, F14, F16-F19 and F21-F23, and thus, the electronic device 100 may map the baseline functions F5, F13, F15, and F20 to the GWO algorithm, as shown in Table 4 above.

The HBA algorithm may have relatively better optimization performance in baseline functions F7 and F12 compared to the other baseline functions F1-F6, F8-F11 and F13-F23, and thus, the electronic device 100 may map the baseline functions F7 and F12 to the HBA algorithm. The PSO algorithm may have relatively better optimization performance in baseline functions F8, F12, and F19 compared to the other baseline functions F1-F7, F9-F11, F13-F18 and F20-F23, and thus, the electronic device 100 may map the baseline functions F8, F12, and F19 to the PSO algorithm. The SSA algorithm may have relatively better optimization performance in baseline functions F6, F16, F17, F18, F21, F22, and F23 compared to the other baseline functions F1-F5, F7-F15, F19 and F20, and thus, the electronic device 100 may map the baseline functions F6, F16, F17, F18, F21, F22, and F23 to the SSA algorithm.

In an embodiment, the electronic device 100 may be configured to evaluate parameter combinations through an objective function. In other words, the electronic device 100 may be configured to calculate objective function values for the parameter combinations. In one example, each parameter combination may include one or more parameters (e.g., the parameters in Table 1 above). Equation 1 below shows an example objective function.

$$f ( θ ) = \sqrt{\frac{1}{n} {\sum }_{t = 1}^{n} {\{ {V}_{sim} ( θ , {I}_{ref} ( t ) ) - {V}_{ref} ( {I}_{ref} ( t ) ) \}}^{2}} \qquad Equation 1$$

In Equation 1 above, θ denotes a parameter combination, and ƒ(θ) may be referred to as an objective function value of the parameter combination. θ may include one or more of the parameters in Table 1 above. Vₛᵢₘ denotes a simulated voltage. The electronic device 100 may be configured to store a simulator corresponding to the battery model 110. The simulator may calculate and/or output Vₛᵢₘ by simulating the operation of the battery model 110 based on θ and I_{ref}. In Equation 1above, V_{ref} and I_{ref} denote reference voltage data and reference current data, respectively.

The electronic device 100 may be configured to generate the distribution of the parameter combinations and the objective function value of each parameter combination using a neural network, which will be described later, and thus identify the most effective optimization technique for the generated distribution and switch from the current optimization technique to the identified optimization technique. The electronic device 100 may be configured to strategically perform the switching of the optimization technique through quantitative analysis of a current situation (or current state) (e.g., the distribution of the parameter combinations and the objective function value of each parameter combination).

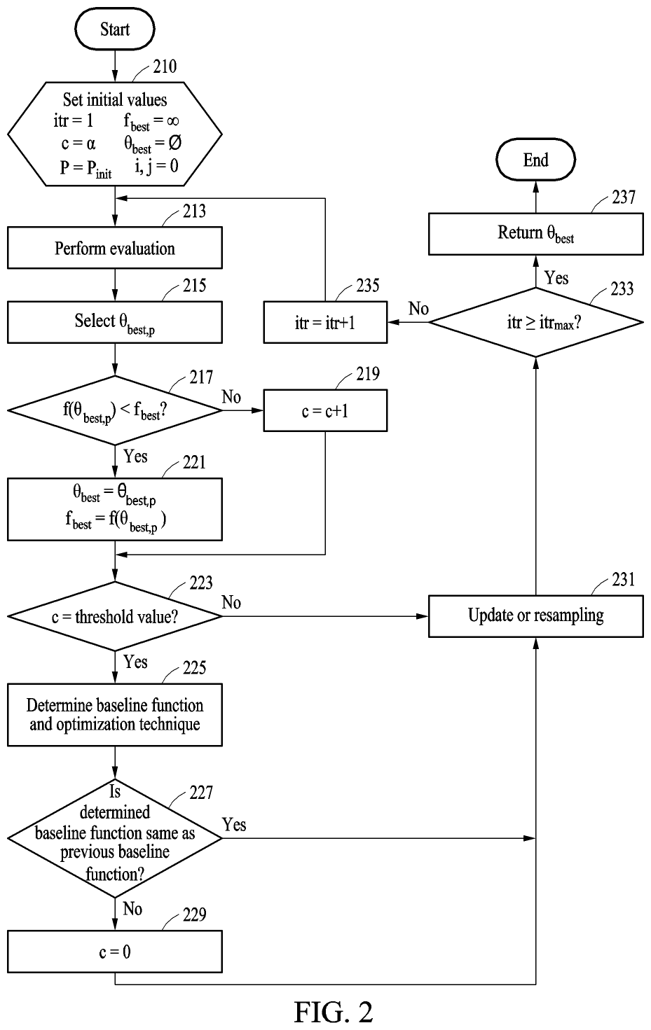

Hereinafter, a battery model optimization method will be described with reference to FIGS. 2 through 5 according to one or more embodiments.

FIGS. 2 through 4 illustrate an example battery model optimization method according to one or more embodiments.

Referring to FIG. 2, in operation 210, the electronic device 100 may set initial values. For example, the electronic device 100 may set an iteration (hereinafter, itr) to 1 and set a count c to α. Here, a may be an integer less than or equal to N, and N may denote the number of parameter combinations. The electronic device 100 may set P to Pᵢₙᵢₜ, ƒ_{best} to ∞, θ_{best} to a null set (or a row vector including zero), and i and j each to “0”.

P may denote a set of parameter combinations (or a matrix including parameter combinations). Pᵢₙᵢₜ denotes initial parameter combinations, and may be parameter combinations initially randomly extracted by the electronic device 100 in a multidimensional space. ƒ_{best} may be the best objective function value obtained when a battery model optimization method (or parameter optimization) is performed up to a given iteration. In operation 210, the electronic device 100 may set ƒ_{best} to ∞. θ_{best} may be the best parameter combination determined when a battery model optimization method (or parameter optimization) is performed to a given iteration, and may be a parameter combination having ƒ_{best}. i may denote an index of a baseline function, and j may denote an index of an optimization technique.

In operation 213, the electronic device 100 may perform an evaluation. In one example, the electronic device 100 may be configured to calculate objective function values for the parameter combinations in P.

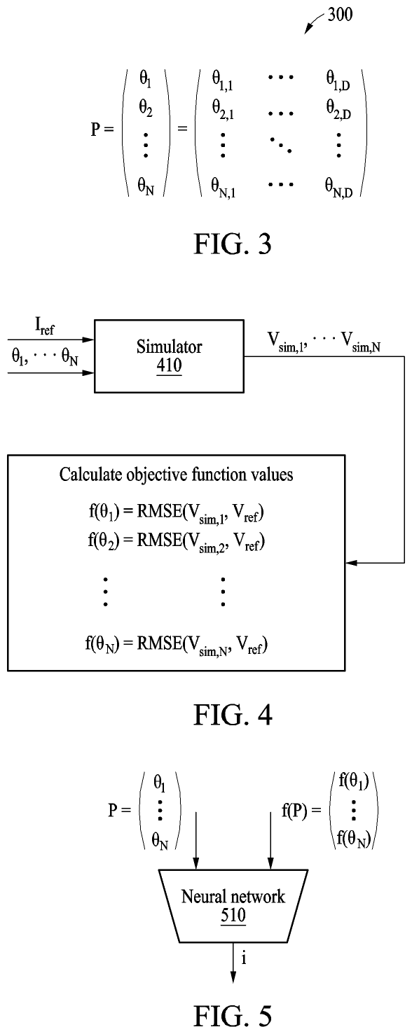

P may be in the form of a matrix P 300, as shown in FIG. 3, and may include parameter combinations θ₁, θ₂, . . . , θ_{N}. The parameter combination θ₁, θ₂, . . . , θ_{N} may each be a row vector of P 300. In one example, the parameter combinations θ₁, θ₂, . . . , θ_{N} may each include one or more parameters (e.g., at least one of the parameters in Table 1 above).

The electronic device 100 may be configured to calculate voltages (or simulated voltages) using a simulator for simulating the operation of the battery model 110, the parameter combinations (e.g., θ₁, θ₂, . . . , θ_{N}), and the reference current data I_{ref}.

In the example shown in FIG. 4, a simulator 410 may calculate voltages (or simulated voltages) V_{sim,1}, . . . , V_{sim,N} by simulating the operation of the battery model 110 based on the reference current data I_{ref} and the parameter combinations (e.g., θ₁, θ₂, . . . , θ_{N}). For example, the simulator 410 may calculate the voltage V_{sim,1} by simulating the operation of the battery model 110 to which the corresponding parameter combination θ₁ is applied when receiving the reference current data I_{ref}. The calculated voltage V_{sim,1} may be, for example, in the form of a vector, and may include a voltage value at t=1 to a voltage value at t=n. Similarly, the simulator 410 may calculate the voltage V_{sim,N} by simulating the operation of the battery model 110 to which the corresponding parameter combination θ_{N} is applied when receiving the reference current data I_{ref}. The voltage V_{sim,N} may be, for example, in the form of a vector, and may include a voltage value at t=1 to a voltage value at t=n.

The electronic device 100 may be configured to calculate the objective function values of the parameter combinations θ₁, θ₂, . . . , θ_{N} using the calculated voltages V_{sim,1}, . . . , V_{sim,N}, the reference voltage data V_{ref}, and an objective function (e.g., the objective function of Equation 1 above). The objective function may be a function that calculates a root-mean-square error (RMSE) between the voltage calculated by the simulator 410 and the reference voltage data. The electronic device 100 may calculate the objective function values of the parameter combinations (e.g., θ₁, θ₂, . . . , θ_{N}), by applying the calculated voltages V_{sim,1}, . . . V_{sim,N} and the reference voltage data V_{ref} to the objective function. For example, the electronic device 100 may calculate

$$RMSE ( {V}_{sim , 1} , {V}_{ref} ) = \sqrt{\frac{1}{n} {\sum }_{t = 1}^{n} {\{ {V}_{sim , 1} ( t ) - {V}_{ref} ( t ) \}}^{2}}$$

as the objective function value ƒ(θ₁) of the parameter combination θ₁, and calculate

$$RMSE ( {V}_{sim , N} , {V}_{ref} ) = \sqrt{\frac{1}{n} {\sum }_{t = 1}^{n} {\{ {V}_{sim , N} ( t ) - {V}_{ref} ( t ) \}}^{2}}$$

as the objective function value ƒ(θ_{N}) of the parameter combination θ_{N}.

Thus, as described above, the parameter combination may be evaluated better as the objective function value is calculated smaller.

Returning to FIG. 2, in operation 215, the electronic device 100 may be configured to select θ_{best,p}. θ_{best,p} may be a parameter combination evaluated as having the best performance in a given iteration. For example, when the least of the objective function values ƒ(θ₁), . . . , ƒ(θ_{N}) calculated at itr=4 is ƒ(θ_{N}), ƒ(θ_{best,p})=ƒ(θ_{N}) may be satisfied at itr=4, and the electronic device 100 may determine θ_{N} as θ_{best,p}.

In operation 217, the electronic device 100 may be configured to determine if ƒ(θ_{best,p})<ƒ_{best}. If itr=1, ƒ_{best} is ∞ as described in operation 210, and thus, the electronic device 100 may determine ƒ(θ_{best,p}) is less than ƒ_{best}. If ƒ(θ_{best,p})=ƒ(θ_{N}) at itr=4, the electronic device 100 may determine whether ƒ(θ_{N}) is less than ƒ_{best}. In one example, ƒ_{best} may correspond to the best objective function value when the method is performed from itr=1 through itr=3.

If ƒ(θ_{best,p}) is greater than or equal to ƒ_{best}, the electronic device 100 may be configured to update (or accumulate) the count c (e.g., c=c+1) in operation 219. When the evaluation of θ_{best} is not as good as the evaluation of θ_{best,p}, the electronic device 100 may update (or accumulate) the count c so as to accumulate a penalty for the optimization technique that is currently performed.

If ƒ(θ_{best,p}) is less than ƒ_{best}, the electronic device 100 may be configured to determine θ_{best,p} as θ_{best} and ƒ(θ_{best,p}) as (best in operation 221.

In operation 223, the electronic device 100 may be configured to determine whether the count c (or the accumulated count c) corresponds to a threshold value (e.g., α). The electronic device 100 may determine whether a switching criterion is satisfied.

When the count c (or the accumulated count c) does not correspond to a threshold value (e.g., when the count c is less than the threshold value (e.g., α)), the electronic device 100 may be configured to perform sample update or resampling in operation 231. In one example, the sample update may be updating P, and the resampling may be extracting (or sampling) again new parameter combinations by the electronic device 100 from an area other than an area in which the parameter combinations in P are distributed.

When the count c (or the accumulated count c) corresponds to the threshold value, the electronic device 100 may be configured to determine a baseline function and an optimization technique in operation 225. In an example given iteration, the electronic device 100 may determine one of the baseline functions in consideration of the distribution of the parameter combinations and the objective function values in the given iteration through a neural network (e.g., a neural network 510 to be described later with reference to FIG. 5). For example, if itr=4, the electronic device 100 may determine one of the baseline functions (e.g., the baseline functions in Table 3 and Table 3 above) in consideration of the distribution of the parameter combinations (e.g., θ₁, θ₂, . . . , θ_{N}) at itr=4 and the objective function values (ƒ(θ₁), . . . , ƒ(θ_{N})) at itr=4 through the neural network (e.g., the neural network 510 to be described later with reference to FIG. 5).

The electronic device 100 may be configured to select one from a plurality of optimization techniques based on the determined baseline function. For example, when the electronic device 100 identifies/determines the baseline function F₅, the electronic device 100 may select the GWO algorithm mapped with the baseline function F₅. The selected GWO algorithm may be the same or different from the optimization technique in the previous iteration. If the baseline function at itr=3 is the baseline function F₂, the optimization algorithm when itr=3 may be the BES algorithm. In one example, the GWO algorithm selected at itr=4 is different from the optimization algorithm at itr=3. At itr=4, the optimization technique may be switched. However, if the baseline function at itr=3 is the baseline function F₁₃, the optimization algorithm at itr=3 is the GWO algorithm. In one example, the GWO algorithm selected at itr=4 is the same as the optimization algorithm at itr=3, and thus, the optimization technique may not be switched at itr=4.

An example neural network, which may be configured to identify/determine the baseline function, and identify/determine the corresponding optimization technique, will be described later.

In operation 227, the electronic device 100 may be configured to determine whether the identified baseline function is the same as the previous baseline function. In one example, the previous baseline function may be the baseline function in the previous iteration, and thus the electronic device 100 may determine whether the baseline function is changed. For example, at itr=4, the electronic device 100 may determine the baseline function F₅. The electronic device 100 may determine whether the determined baseline function F₅ is the same as the baseline function at itr=3.

The electronic device 100 may be configured to perform operation 231 when the determined baseline function is the same as the previous baseline function.

When the determined baseline function is not the same as the previous baseline function, the electronic device 100 may be configured to initialize the count c (e.g., c=0) in operation 229. When the count c is initialized, the electronic device 100 may perform operation 231

At itr=1, the count c may be set to a threshold value (e.g., α) according to the initial values set in operation 210. In one example, the electronic device 100 may determine that the count c is equal to the threshold value in operation 223 and perform operation 225 and operation 227. Since itr=1, a previous baseline function may be absent. Thus, the electronic device 100 may initialize the count c in operation 229.

As non-limiting examples, the order of operations 225, 227, and 229 may be changed. For example, at itr=4, when the count c corresponds to the threshold value, the electronic device 100 may be configured to determine one of the baseline functions in consideration of the distribution of the parameter combinations (e.g., θ₁, θ₂, . . . , θ_{N}) and the objective functions (ƒ(θ₁), . . . , ƒ(θ_{N})) at itr=4 through the neural network. When the baseline function is determined, the electronic device 100 may determine whether the determined baseline function is the same as the previous baseline function. When the determined baseline function is not the same as the previous baseline function, the electronic device 100 may determine an optimization technique based on the determined baseline function and initialize the count c. When the count c is initialized, the electronic device 100 may perform operation 231. The electronic device 100 may perform operation 231 when the determined baseline function is the same as the previous baseline function.

In operation 231, the electronic device 100 may be configured to update P or perform resampling. In one embodiment, during a portion of itrs previous to the current itr, ƒ_{best} may not change. In response to detecting that ƒ_{best} is not changed during the portion of itrs previous to he current itr (e.g., c≥3α), the electronic device 100 may perform resampling at the current itr, and otherwise (e.g., c<3α), may update P.

For example, the current itr may be “100”. During a portion (e.g., itr=80 through itr=99) of itrs (itr=1 through itr=99) previous to the current itr=100, ƒ_{best} may not change. Since the parameter combinations of P are clustered around local optima, ƒ_{best} may not change during the portion (e.g., itr=80 through itr=99) of previous itrs. This may cause a situation where c≥3α at the current itr=100. In this case, it may be difficult for the electronic device 100 to obtain better results even if parameter optimization continues. As non-limiting examples, the electronic device 100 may extract or sample again parameter combinations by searching again the area (or space) other than the area where the parameter combinations of P are distributed. The electronic device 100 may extract or sample new parameter combinations, thereby improving the possibility of obtaining better solutions.

The electronic device 100 may be configured to update P if resampling is not to be performed (e.g., if c<3α). According to an embodiment, when the optimization technique is switched, the electronic device 100 may update P in consideration of the switched optimization technique.

When P is updated or resampling is performed, the electronic device 100 may determine whether itr is greater than or equal to itrₘₐₓ in operation 233. Here, itrₘₐₓ may be the maximum number of iterations.

If itr is less than itrₘₐₓ, the electronic device 100 may be configured to update itr (e.g., itr=itr+1) in operation 235.

If itr is greater than or equal to itrₘₐₓ, the electronic device 100 may be configured to return θ_{best} in operation 237.

In one example, when θ_{best} at a predetermined iteration corresponds to desired particular combinations, the electronic device 100 may be configured to stop iteration and return θ_{best} at the predetermined iteration.

θ_{best} may be the optimal parameter of the battery model 110, and the electronic device 100 may be configured to apply θ_{best} to the battery model 110. The battery model 110 to which θ_{best} is applied may be provided in various devices (e.g., an electric vehicle, a smartphone, etc.), and may estimate state information (e.g., voltages, states of charge (SOC), states of health (SOH), degrees of deterioration, etc.) of the devices, as non-limiting examples.

FIGS. 5 through 7B illustrate an example electronic device configured to determine a baseline function using a neural network according to one or more embodiments.

Referring to FIG. 5, an example neural network 510 may be configured to analyze a distribution of objective function values corresponding to respective parameter combinations sampled in a multidimensional space, and determine which baseline function, among respective baseline functions, has a pattern that is most similar to the analyzed distribution.

In a given iteration itr, when the count c reaches the threshold value, the example electronic device (e.g., the electronic device 100 in FIG. 1) may input P (e.g., P 300 in FIG. 3) and f(P) to the neural network 510. f(P) may include objective function values of respective parameter combinations. The objective function values may be scalar as a non-limiting example.

The electronic device 100 may determine a baseline function in consideration of a distribution of P (e.g., P 300 in FIG. 3) and f(P) through the neural network 510. In one example, the electronic device 100 may determine the baseline function that matches the distribution of P (e.g., P 300 in FIG. 3) and f(P) through the neural network 510.

The neural network 510 may generate and output the index i of the baseline function as shown in FIG. 5. The electronic device 100 may detect/recognize the baseline function having the index i as output from the neural network 510 and determine it as a baseline function most suitable for a current situation (e.g., parameter combinations in a given iteration and objective function values of the parameter combinations).

In a non-limiting example, the neural network 510 may be a neural network that is trained through a virtual data distribution generated from baseline functions. Supervised learning may be iteratively performed in a manner that parameter combinations and objective function values corresponding to the respective parameter combinations are input to an untrained or in-training neural network and an index of a baseline function is output from the untrained/in-training neural network. As a non-limiting example, the supervised learning may include performing back-propagation learning, such as gradient descent backpropagation learning, based on calculated losses of the output of the untrained or in-training neural network. The neural network 510 may be generated through such supervised learning, and the electronic device 100 may use the neural network 510 to determine (i.e., infer) a baseline function.

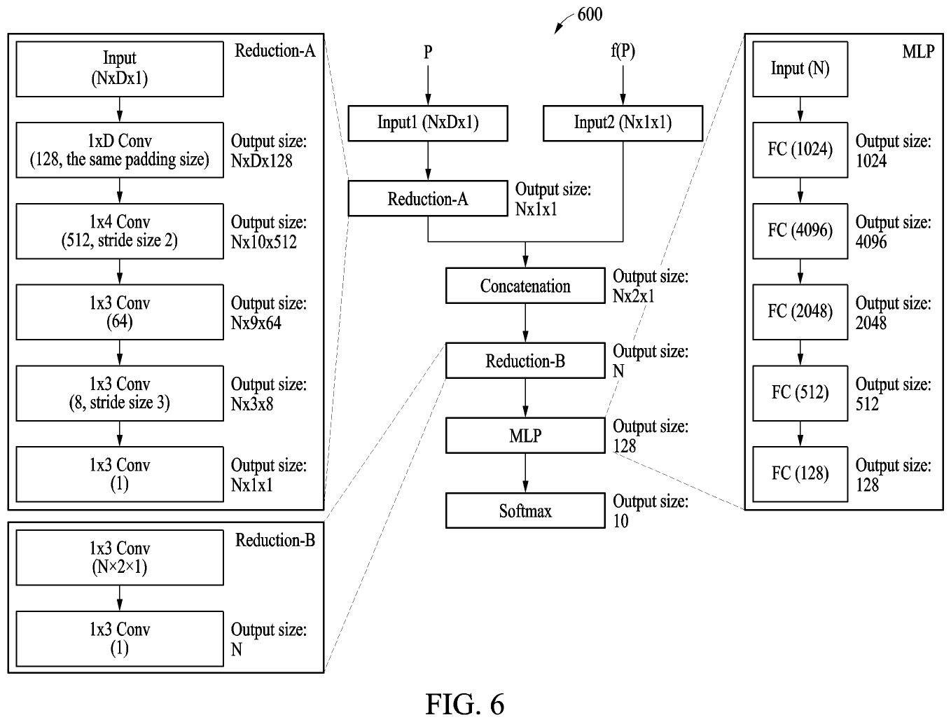

An example neural network 600 is shown in FIG. 6 according to one or more embodiments.

As shown in FIG. 6, the example neural network 600 may include Reduction-A, Reduction-B, and MLP. Reduction-A and Reduction-B may denote deep convolutional layer blocks, and MLP may stand for a multilayer perceptron. Cony and FC may denote a convolutional layer and a fully connected layer, respectively.

The example neural network 600 may include a softmax layer that may output an index i of a baseline function having a pattern that matches the input (e.g., P and/or f(P)) of the neural network 600.

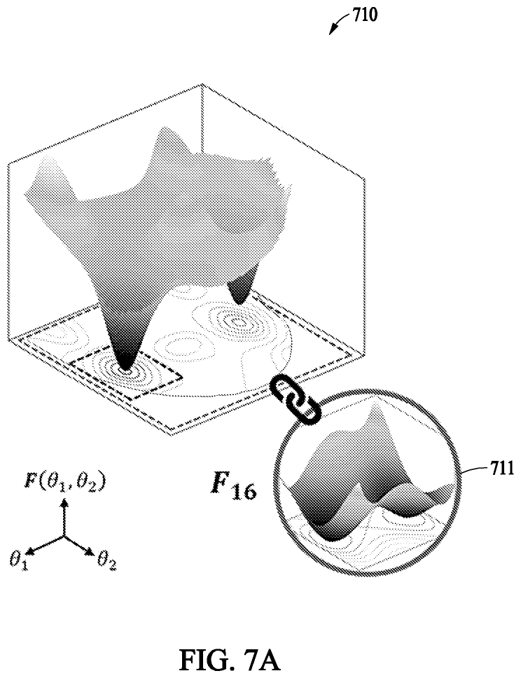

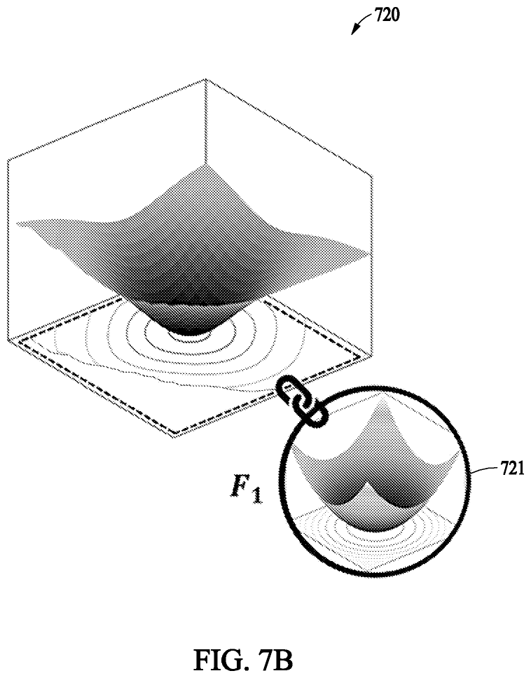

For example, as shown in FIG. 7A, the neural network 600 may infer or figure out (analyze) a distribution of the input (e.g., P and/or f(P)) with a graph 710. The neural network 600 may determine that a baseline function F₁₆ 711 in Table 3 above may be the most similar to the graph 710, among the baseline functions. In one example, the neural network 600 may determine that a distribution of the input (e.g., P and/or f(P)) best matches the baseline function F₁₆ 711. The neural network 600 may output the index “16” of the baseline function F₁₆ 711. As shown in FIG. 7B, the neural network 600 may figure out (or analyze) a distribution of the input (e.g., P and/or f(P)) with a graph 720. The neural network 600 may determine that a baseline function F₁ 721 in Table 2 above may be the most similar to the graph 720, among the baseline functions, and generate and output the index “1” of the baseline function F₁ 721.

The electronic device 100 may be configured to select an optimization technique using the output (e.g., the index of the baseline function) of the neural network 600. For example, when the neural network 600 outputs the index “16”, the electronic device 100 may select the SSA algorithm as an optimization technique mapped with the baseline function F16 using Table 4 above. When the neural network 600 outputs the index “1”, the electronic device 100 may select the BES algorithm as an optimization technique mapped with the baseline function F₁ using Table 4 above.

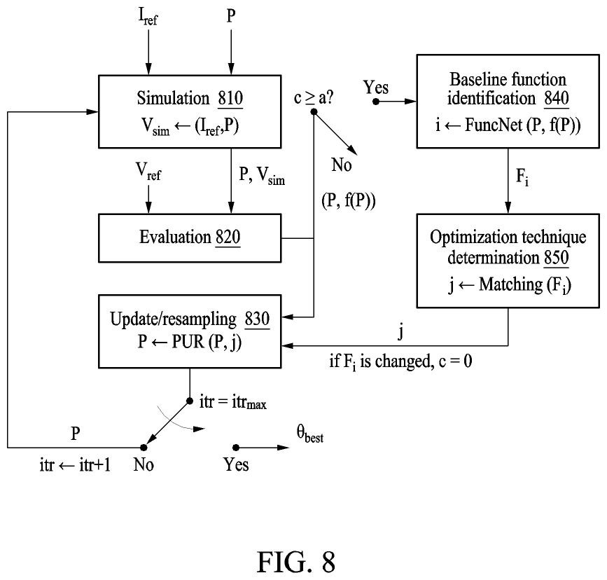

FIG. 8 illustrates an example battery model optimization method according to one or more embodiments.

Referring to FIG. 8, the electronic device 100 may one or more processors configured to execute instructions and one or more memories storing the instructions. The execution of the instructions by the one or more processors may configure the one or more processors to perform any one or any combinations of operations including simulation 810, evaluation 820, update/resampling 830, baseline function identification 840, and optimization technique determination 850. The electronic device 100 may be configured to iteratively perform simulation 810, evaluation 820, and update/resampling 830, and to perform baseline function identification 840 and optimization technique determination 850 when a switching criterion is satisfied.

The description of the operation of the simulator 410 of FIG. 4 may be applicable to simulation 810.

The description of evaluating parameter combinations by the electronic device 100 (e.g., the description of calculating objective function values of the parameter combinations) may be applicable to evaluation 820.

The description of operation 231 of FIG. 2 may be applicable to update/resampling 830. In update/resampling 830, particle update and resampling (PUR) may indicate an operation of updating or resampling P.

The description of operation 225 provided above may apply to baseline function identification 840 and optimization technique determination 850. In an example, FuncNet in baseline function identification 840 may denote the neural network 510 (e.g., the neural network 600) described above. Matching in optimization technique determination 850 may denote an operation of finding an optimization technique that matches (or is mapped to) a baseline function F.

According to optimization technique determination 850, the electronic device 100 may return an index j of the optimization technique. The electronic device 100 may set or initialize the count c to “0” when the baseline function Fi is changed.

Table 5 below shows an example pseudo codes of the battery model optimization method, and Table 6 below shows an example pseudo codes of PUR, according to one or more embodiments.

TABLE 5

```
given
  P2D(·,·), FuncNet(·,·), Matching(·), PUR(·,·)
  I_{ref}, V_{ref}
  itrₘₐₓ, N, D
  lb ∈ [symbol]  ^{D}, the lower bound of parameters
  ub ∈ [symbol]  ^{D}, the upper bound of parameters
end given
procedure SSM(α, β, f)
  initialize
  particles, P~[lb, ub]^{N}
  the best parameter, θ_{best} ← ∅
  the best value set, f_{best}(0) ← ∞
  the count for hybridization criteria, c ← α
  the baseline function and SIA indexes, i, j ← 0
  end initialize
  for itr = 1, . . . , itrₘₐₓ do
    // Evaluation
    for θ′ = θ, ∀θ ∈ P do
      Vₛᵢₘ ← P2D(θ′, I_{ref})
      f(θ′) ← RMSE(Vₛᵢₘ, V_{ref})
      if f(θ′) ← f_{best}(itr − 1) then
        θ_{best} ← θ′
      end if
      f(P) ← f(θ′)
    end for
    f_{best}(itr) ← f(θ_{best})
    // Switching Criterion
    if itr > α then
      $if {f}_{best} ( itr ) > ( 1 - β + \frac{β * itr}{{itr}_{max}} ) * {f}_{best} ( itr - α )$
then
        c ← c + 1
      end if
    end if
    // Particle update and resampling
    P ← PUR(P, j)
  end for
  return θ_{best}
end procedure
```

TABLE 6

```
global variables
  α, β, f
end global variables
procedure PUR(P, j)
  if c < 3α then
    // Swarm behavior
    P ← UPDATE(P, SIAⱼ)
  else
    B ← [lb, ub] − [θₘᵢₙ, θₘₐₓ]
    // Resampling away from current particles
    P~B^{N}
    c ← α
  end if
end procedure
```

In Table 5 above, P2D may denote an electrochemical model, N may denote the number of rows (or the number of parameter combinations) of P (e.g., P 300 of FIG. 3), and D may denote the number of columns (or the number of parameters included in each combination parameter) of P. If D is, for example, “1”, each parameter combination may include, for example, one parameter among the parameters in Table 1 above, and if D is, for example, “20”, each parameter combination may include twenty parameters among the parameters in Table 1 above.

In Table 5 above, β is a constant between “0” and “1”.

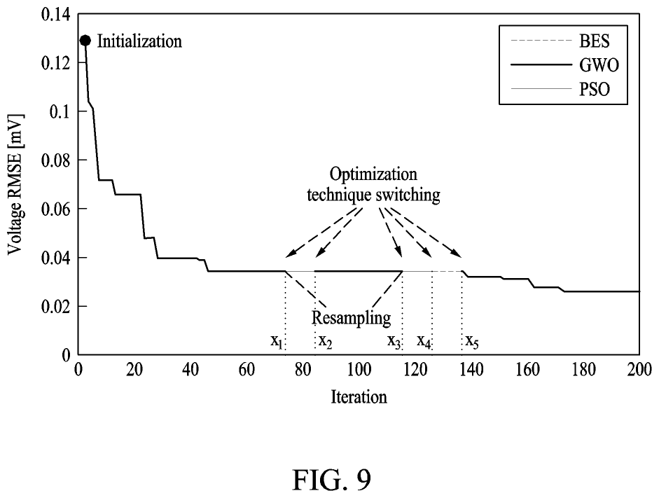

FIG. 9 illustrates an example operation of switching an optimization technique while a battery model optimization method is performed according to one or more embodiments.

While the battery model optimization method is performed, a voltage error (e.g., voltage RMSE) is shown in FIG. 9. In one example, the voltage RMSE of FIG. 9 may correspond to ƒ_{best} described above.

As shown in FIG. 9, the voltage RMSE (e.g., ƒ_{best}) may generally decrease while iterations proceed, and the voltage RMSE (e.g., ƒ_{best}) may be stagnant in some iterations.

Until itr=x₁, an electronic device (e.g., the electronic device 100 of FIG. 1) may be configured to perform parameter optimization according to the GWO algorithm. In one example, at itr=1 through itr=x₁−1, the electronic device 100 may perform parameter optimization according to the GWO algorithm. At itr=x₁, the switching criterion may be satisfied, and the electronic device 100 may switch or change the optimization technique from the GWO algorithm to the PSO algorithm. In some itrs before itr=x₁, the voltage RMSE (e.g., ƒ_{best}) may be almost unchanged, and c≥3α at itr=x₁. The electronic device 100 may perform resampling at itr=x₁ through the switched PSO algorithm.

The electronic device 100 may be configured to switch or change the optimization technique from the PSO algorithm to the GWO algorithm as the switching criterion is satisfied at itr=x₂.

The electronic device 100 may be configured to switch or change the optimization technique from the GWO algorithm to the PSO algorithm as the switching criterion is satisfied at itr=x₃ and perform resampling.

The electronic device 100 may be configured to switch or change the optimization technique from the PSO algorithm to the BES algorithm as the switching criterion is satisfied at itr=x₄.

The electronic device 100 may be configured to switch or change the optimization technique from the BES algorithm to the GWO algorithm as the switching criterion is satisfied at itr=x₅.

The electronic device 100 may be configured to perform parameter optimization through the GWO algorithm, and terminate parameter optimization when an optimization end event occurs (e.g., when the maximum number of iterations is reached or when a desired parameter combination is derived).

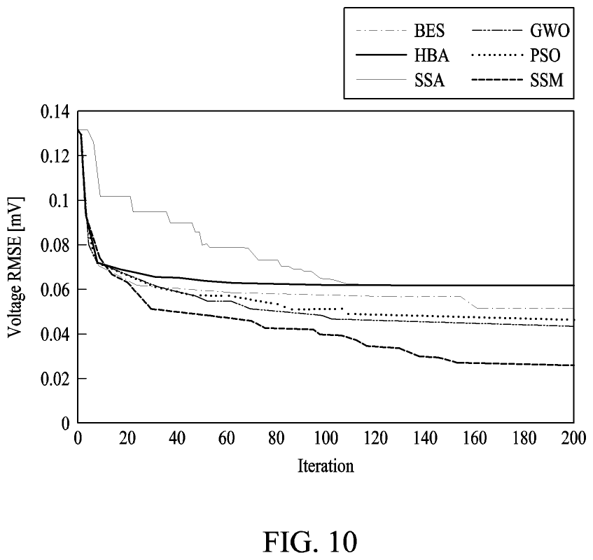

FIG. 10 illustrates an example comparison in a voltage error measurement between a battery model optimization method according to one or more embodiments and typical optimization techniques.

Referring to FIG. 10, voltage errors (e.g., voltage RMSE) measured when typical optimization techniques (e.g., BES algorithm, GWO algorithm, HBA algorithm, PSO algorithm, and SSA algorithm) are performed and a voltage error measured when strategically switching metaheuristics (SSM) is performed are shown. SSM corresponds to a battery model optimization method according to one embodiment.

The voltage error of SSM at the same itr may be lower than the voltage errors of the typical optimization techniques, and the voltage error of SSM may decrease more quickly than the voltage errors of the typical optimization techniques throughout all itrs. This may indicate that the objective function value of SSM converges quickly and accurately compared to the objective function values of the typical optimization techniques. SSM may perform optimization faster than typical optimization techniques.

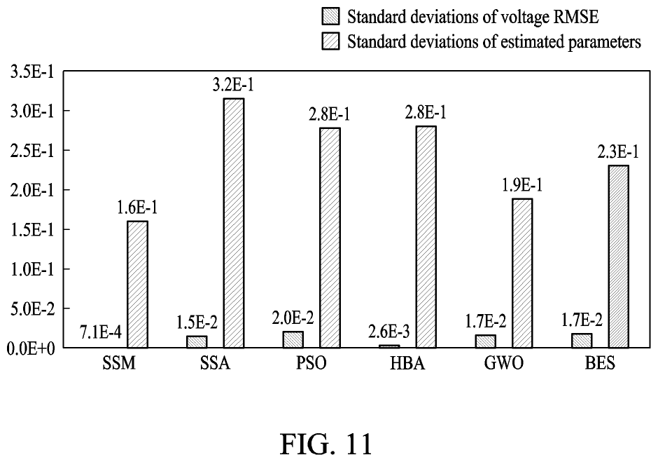

FIG. 11 illustrates an example comparison in a standard deviation of voltage errors and a standard deviation of estimated parameters when a battery model optimization method according to one or more embodiments and a typical single optimization technique are performed.

Referring to FIG. 11, the standard deviation of the voltage RMSE of SSM is lower than the standard deviation of the voltage RMSE of each of the typical optimization techniques, and the standard deviation of parameters estimated (or optimized) by SSM is lower than the standard deviation of parameters estimated (or optimized) by each of the typical optimization techniques. Thus, this may indicate that SSM derives consistent results compared to the typical optimization techniques.

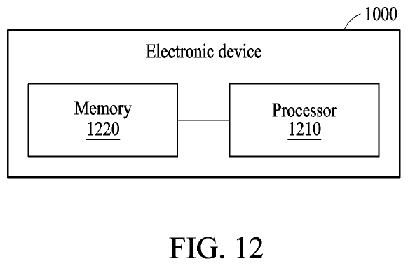

FIG. 12 illustrates an example electronic device according to one or more embodiments.

Referring to FIG. 12, the electronic device 1000 (e.g., the electronic device 100 in FIG. 1) may include a processor 1210 and a memory 1220.

The memory 1220 may store one or more instructions (e.g., instructions related to a battery model optimization method) to be executed by the processor 1210.

The memory 1220 may store an operation result of the processor 1210.

The processor 1210 may be configured to perform any one or any combinations of operations implemented in the battery model optimization method by executing the one or more instructions.

The processor 1210 may perform first parameter optimization of the battery model 110 through a first optimization technique. In an example, the processor 1210 may calculate objective function values of parameter combinations to which the first optimization technique is applied, in a given iteration. For example, the processor 1210 may calculate voltages (e.g., simulated voltages) using the simulator 410 for simulating the battery model 110, the parameter combinations, and reference current data. The processor 1210 may calculate the objective function values of the parameter combinations using the calculated voltages and reference voltage data. The processor 1210 may select one of the calculated objective function values. The processor 1210 may compare the selected objective function value (e.g., ƒ(θ_{best,p})) with a best objective function value (e.g., ƒ_{best} of operation 217 of FIG. 2) determined prior to the given iteration. The processor 1210 may accumulate a count when the selected objective function value is greater than or equal to the best objective function value (e.g., ƒ_{best} of operation 217 of FIG. 2), and determine the selected objective function value as a new best objective function value (e.g., ƒ_{best}=ƒ(θ_{best,p}) of operation 221 of FIG. 2) when the selected objective function value is less than the objective function value (e.g., ƒ_{best} of operation 217 of FIG. 2).

The processor 1210 may determine whether a switching criterion for switching an optimization technique is satisfied, based on a count (e.g., the count c described above) accumulated while performing the first parameter optimization. For example, the processor 1210 may determine that the switching criterion is satisfied, when the accumulated count reaches a threshold value.

The processor 1210 may switch from the first optimization technique to a second optimization technique when the switching criterion is satisfied. In an example, the processor 1210 may determine one of a plurality of baseline functions, using parameter combinations determined when the switching criterion is satisfied (e.g., parameter combinations θ₁, θ₂, . . . , N₁ at itr=4 when the switching criterion is satisfied at itr=4), objective function values (e.g., ƒ(θ₁), . . . , ƒ(θ_{N})) of the parameter combinations, and the neural network 510. For example, the processor 1210 may determine the baseline function in consideration of the distribution of the parameter combinations and the objective function values through the neural network 510. The processor 1210 may select a second optimization technique based on the determined baseline function. For example, the processor 1210 may determine whether the determined baseline function corresponds to a baseline function for evaluating a performance of the second optimization technique among a plurality of optimization techniques. The processor 1210 may select the second optimization technique when the determined baseline function corresponds to a baseline function for evaluating the performance of the second optimization technique.

The processor 1210 may initialize the accumulated count when switching from the first optimization technique to the second optimization technique.

The processor 1210 may perform second parameter optimization of the battery model 110 through the second optimization technique. In an example, the processor 1210 may update parameter combinations determined when the switching criterion is satisfied through the second optimization technique. The processor 1210 may extract parameter combinations from an area other than a distribution area of parameter combinations determined when the switching criterion is satisfied, in response to a predetermined condition being satisfied (e.g., if c≥3α).

The processor 1210 may detect an optimization end event while performing the second parameter optimization. The optimization end event may include, for example, a case where itr reaches itrₘₐₓ or a case where θ_{best} corresponds to a desired parameter combination, but is not limited thereto.

When the processor 1210 detects an optimization end event, the best parameter combination determined while performing the battery model optimization method (e.g., θ_{best}) may be determined as an optimal parameter of the battery model 110.

The description provided with reference to FIGS. 1 through 11 may apply to the battery model optimization method of the electronic device 100 of FIG. 12.

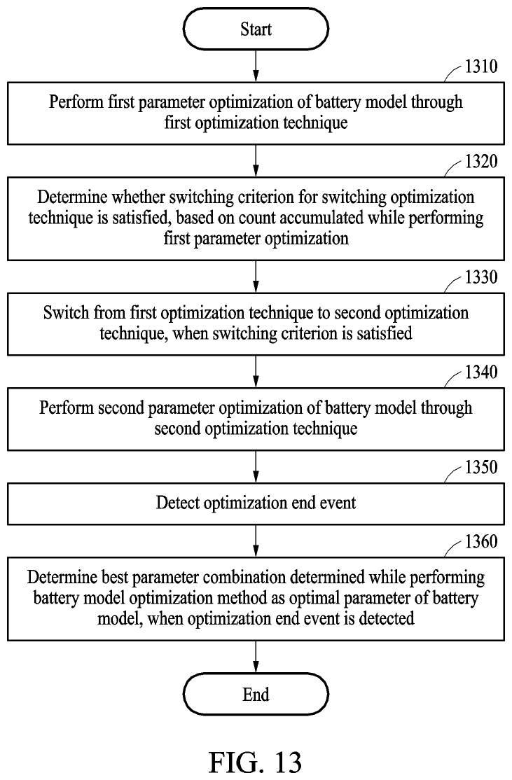

FIG. 13 illustrates an example battery model optimization method performed by an electronic device according to one or more embodiments. The electronic device (e.g., the electronic device 100 in FIG. 1 and/or the electronic device 1000 in FIG. 12) may include one or more processors (e.g., the processor 1210 in FIG. 12) configured to execute instructions and one or more memories (e.g., the memory 1220 in FIG. 12) storing the instructions. The execution of the instructions by the one or more processors may configure the one or more processors to perform any one or any combinations of operations or methods of battery model optimization as described herein.

Referring to FIG. 13, in operation 1310, the electronic device 100 may perform first parameter optimization of a battery model through a first optimization technique.

In operation 1320, the electronic device 100 may determine whether a switching criterion for switching an optimization technique is satisfied, based on a count accumulated while performing the first parameter optimization.

In operation 1330, the electronic device 100 may switch from the first optimization technique to a second optimization technique when the switching criterion is satisfied.

In operation 1340, the electronic device 100 may perform second parameter optimization of the battery model through the second optimization technique.

In operation 1350, the electronic device 100 may detect an optimization end event.

In operation 1360, the electronic device 100 may determine a best parameter combination determined while performing the battery model optimization method as an optimal parameter of the battery model, when the optimization end event is detected.

The description provided with reference to FIGS. 1 through 12 may apply to the battery model optimization method of FIG. 13.

The processors, memories, electronic devices, apparatuses, electronic devices 100 and 1000, and other apparatuses, devices, and components described herein with respect to FIGS. 1-13 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-13 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A processor-implemented method, comprising:
performing first parameter optimization of a battery model through a first predetermined optimization technique;
switching, based on a count accumulated while performing the first parameter optimization indicating that a switching criterion has been met, from the first optimization technique to a second predetermined optimization technique;
performing second parameter optimization of the battery model through the second predetermined optimization technique; and
determining a final parameter combination as an optimized parameter of the battery model, in response to an occurrence of an optimization end event during the performance of the second parameter optimization.

2. The method of claim 1, wherein the performing of the first parameter optimization comprises:
generating, in a current iteration of the first parameter optimization, objective function values for parameter combinations to which the first optimization technique is applied;
selecting one of the generated objective function values;
comparing the selected one objective function value with a previously determined best objective function value, determined in a previous iteration of the first parameter optimization;
accumulating the count when the selected one objective function value is determined to be greater than or equal to the previously determined best objective function value; and
determining the selected one objective function value as a new best objective function value when the selected one objective function value is determined to be less than the previously determined best objective function value.

3. The method of claim 2, wherein the generating of the objective function values for the parameter combinations comprises:
calculating voltages using a simulator configured to simulate the battery model, the parameter combinations, and reference current data; and
calculating the objective function values for the parameter combinations using the calculated voltages and reference voltage data.

4. The method of claim 1, wherein the switching criterion is satisfied when the accumulated count reaches a threshold value.

5. The method of claim 1, wherein the switching comprises:
determining one of a plurality of baseline functions using parameter combinations determined when the switching criterion is satisfied, objective function values for the determined parameter combinations, and a neural network; and
selecting the second optimization technique based on the determined baseline function.

6. The method of claim 5, wherein the determining of one of the plurality of baseline functions comprises determining the baseline function in consideration of a distribution of the determined parameter combinations and the objective function values through the neural network.

7. The method of claim 5, wherein the selecting of the second optimization technique comprises:
determining whether the determined baseline function corresponds to a baseline function for evaluating a performance of the second optimization technique among a plurality of optimization techniques; and
selecting the second optimization technique when the determined baseline function corresponds to the baseline function.

8. The method of claim 5, further comprising initializing the accumulated count.

9. The method of claim 1, wherein the performing of the second parameter optimization comprises updating parameter combinations determined when the switching criterion is satisfied through the second optimization technique.

10. The method of claim 1, wherein the performing of the second parameter optimization comprises, in response to a predetermined condition being satisfied, extracting parameter combinations from an area other than a distribution area of parameter combinations determined when the switching criterion is satisfied.

11. An electronic device, comprising:
one or more processors configured to execute instructions; and
a memory configured to store the instructions,
wherein the execution of the instructions by the one or more processors configures the one or more processors to:
perform first parameter optimization of a battery model through a first predetermined optimization technique;
switch, based on a count accumulated while performing the first parameter optimization indicating that a switching criterion has been met, from a first optimization technique to a second predetermined optimization technique;
perform second parameter optimization of the battery model through the second optimization technique; and
determine a final parameter combination as an optimized parameter of the battery model, in response to an occurrence of an optimization end event during the performance of the second parameter optimization.

12. The electronic device of claim 11, wherein the one or more processors are further configured to:
generate, in a current iteration of the first parameter optimization, objective function values for parameter combinations to which the first optimization technique is applied;
select one of the generated objective function values;
compare the selected one objective function value with a previously determined best objective function value, determined in a previous iteration;
accumulate the count when the selected one objective function value is determined to be greater than or equal to the previously determined best objective function value; and
determine the selected one objective function value as a new best objective function value when the selected one objective function value is determined to be less than the previously determined best objective function value.

13. The electronic device of claim 12, wherein the one or more processors are further configured to:
calculate voltages using a simulator configured to simulate the battery model, the parameter combinations, and reference current data; and
calculate the objective function values for the parameter combinations using the calculated voltages and reference voltage data.

14. The electronic device of claim 11, wherein the one or more processors are further configured to determine that the switching criterion is satisfied, when the accumulated count reaches a threshold value.

15. The electronic device of claim 11, wherein the one or more processors are further configured to:
determine one of a plurality of baseline functions using parameter combinations determined when the switching criterion is satisfied, objective function values for the parameter combinations, and a neural network; and
select the second optimization technique based on the determined baseline function.

16. The electronic device of claim 15, wherein the one or more processors are further configured to determine the baseline function in consideration of a distribution of the parameter combinations and the objective function values through the neural network.

17. The electronic device of claim 15, wherein the one or more processors are further configured to:
determine whether the determined baseline function corresponds to a baseline function for evaluating a performance of the second optimization technique among a plurality of optimization techniques; and
select the second optimization technique when the determined baseline function corresponds to the baseline function.

18. The electronic device of claim 15, wherein the one or more processors are further configured to initialize the accumulated count.

19. The electronic device of claim 11, wherein the one or more processors are further configured to update parameter combinations determined when the switching criterion is satisfied through the second optimization technique.

20. The electronic device of claim 11, wherein the one or more processors are further configured to, in response to a predetermined condition being satisfied, extract parameter combinations from an area other than a distribution area of parameter combinations determined when the switching criterion is satisfied.
